(19) United States
(12) Patent Application Publication
(10) Pub. No.: US 2021/0176879 A1
(43) Pub. Date: Jun. 10, 2021

(54) DISPLAY MODULE AND METHOD OF FABRICATING THE SAME

(71) Applicant: Samsung Display Co., Ltd., Yongin-si (KR)

(72) Inventors: Seungmin SONG, Gwangju (KR); Ki Nyeng KANG, Sejong-si (KR); Seonbeom JI, Seoul (KR); Taehoon YANG, Yongin-si (KR); Jonghyun CHOI, Seoul (KR)

(21) Appl. No.: 16/986,880

(22) Filed: Aug. 6, 2020

(30) Foreign Application Priority Data
Dec. 4, 2019 (KR) 10-2019-0159945

(51) Int. Cl. H05K 5/03; H05K 5/00

(52) U.S. Cl. CPC H05K 5/03; H05K 5/0017

(57) ABSTRACT

A method of fabricating a display device may include preparing a display panel, attaching a film portion to the display panel, forming an alignment key on or in the film portion, recognizing the alignment key using an alignment module with a camera, aligning a window to the film portion using the alignment module, removing at least a portion of the film portion, and combining the display panel with the window.

### CROSS-REFERENCE TO RELATED APPLICATIONS

This application claims priority from and the benefit of Korean Patent Application No. 10-2019-0159945, filed on Dec. 4, 2019, which is hereby incorporated by reference for all purposes as if fully set forth herein.

### BACKGROUND OF THE INVENTION

### Field

Embodiments/implementations of the invention relate generally to a display module with improved reliability and a method of fabricating the same.

### Discussion of the Background

Various display devices are being developed for use in multimedia devices such as televisions, mobile phones, navigation systems, computer monitors, gaming machines, and the like. The display device includes a display panel providing image information to a user and a window protecting the display panel. The window may be combined to the display panel. To combine the window to the display panel, it is necessary to align the window to the display panel.

The above information disclosed in this Background section is only for understanding of the background of the inventive concepts, and, therefore, it may contain information that does not constitute prior art.

### SUMMARY

Devices constructed according to embodiments of the invention are capable of providing a display module with improved reliability and methods according to exemplary implementations are capable of fabricating the same.

Additional features of the inventive concepts will be set forth in the description which follows, and in part will be apparent from the description, or may be learned by practice of the inventive concepts

According to an embodiment of the inventive concepts, a method of fabricating a display device may include preparing a display panel, attaching a film portion to the display panel, forming an alignment key on or in the film portion, recognizing the alignment key using an alignment module with a camera, aligning a window to the film portion using the alignment module, removing at least a portion of the film portion, and combining the display panel with the window.

In an embodiment, the film portion may include an optical film and a protection film disposed on the optical film, and the forming of the alignment key on or in the film portion is may include forming the alignment key on or in a top surface of the protection film.

In an embodiment, the removing of at least the portion of the film portion may include removing the protection film.

In an embodiment, the forming of the alignment key may include patterning a top surface of the film portion using a laser beam.

In an embodiment, the forming of the alignment key may include printing an ink on a top surface of the film portion.

In an embodiment, the forming of the alignment key may be performed before the attaching of the film portion to the display panel.

In an embodiment, the forming of the alignment key may be performed after the attaching of the film portion to the display panel.

In an embodiment, the display panel may include a first region, which includes a first edge, a second edge extending in a direction crossing the first edge, a third edge parallel to the first edge, and a fourth edge parallel to the second edge, a second region extended from the first edge, a third region extended from the second edge, a fourth region extended from the third edge, and a fifth region extended from the fourth edge. At least a portion of each of the second to fifth regions may be bent.

In an embodiment, the alignment key may be formed on at least one of the second to fifth regions.

In an embodiment, the alignment key may be formed on the first region.

In an embodiment, the forming of the alignment key may include forming a plurality of alignment keys in at least two different shapes.

In an embodiment, the display panel may include a display region and a is non-display region adjacent to the display region. The alignment key may be formed at a position overlapped with the display region.

In an embodiment, the alignment module may further include a control unit. The method may further include storing position information on an aligned position of the window, in the control unit.

In an embodiment, the method may further include aligning the window, using the position information stored in the control unit, after the removing of at least the portion of the film portion.

In an embodiment, the recognizing of the alignment key and the aligning of the window may be performed simultaneously.

In an embodiment, the alignment key may provide in plural. The film portion may include a first alignment region, a second alignment region adjacent to the first alignment region, a third alignment region adjacent to the first alignment region and spaced apart from the second alignment region, and a fourth alignment region adjacent to the second and third alignment regions. The forming of the alignment key may include forming the plurality of alignment keys on or in at least two regions of the first to fourth alignment regions.

According to an embodiment of the inventive concepts, a display module may include a display panel including a display region and a non-display region adjacent to the display region, an optical film disposed on the display panel, and a protection film disposed on the optical film. At least one alignment key may be provided on or in a top surface of the protection film.

In an embodiment, the alignment key may be overlapped with the display region, when viewed in a plan view.

In an embodiment, the alignment key may be defined by a hollow region, which is recessed downward from the top surface of the protection film, and a depth of the hollow region may be smaller than a thickness of the protection film.

In an embodiment, the alignment key may include an ink pattern provided on the top surface of the protection film.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a perspective view illustrating a display device according to an embodiment of the inventive concepts.

FIG. 2 is a perspective view illustrating an exploded structure of a display device according to an embodiment of the inventive concepts.

FIG. 3 is a flow chart illustrating a method of fabricating a display device according to an embodiment of the inventive concepts.

FIG. 4 is a sectional view illustrating a step of forming an alignment key, according to an embodiment of the inventive concepts.

FIG. 5 is a plan view illustrating a film portion according to an embodiment of the is inventive concepts.

FIGS. 6A and 6B are perspective views illustrating a step of attaching a film portion on a display panel, according to an embodiment of the inventive concepts.

FIG. 7 is a perspective view illustrating a part of a method of fabricating a display device, according to an embodiment of the inventive concepts.

FIG. 8 is a perspective view illustrating a step of removing a portion of a film portion, according to an embodiment of the inventive concepts.

FIGS. 9 and 10 are sectional views illustrating a step of combining a window with a display panel, according to an embodiment of the inventive concepts.

FIG. 11 is a sectional view illustrating a step of forming an alignment key on a film portion, according to an embodiment of the inventive concepts.

FIG. 12 is a flow chart illustrating a method of fabricating a display device, according to an embodiment of the inventive concepts.

FIG. 13 is a sectional view illustrating a step of forming an alignment key, according to an embodiment of the inventive concepts.

FIG. 14 is a sectional view illustrating a step of forming an alignment key, according to an embodiment of the inventive concepts.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or is more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing exemplary features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed is substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for is descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for is example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

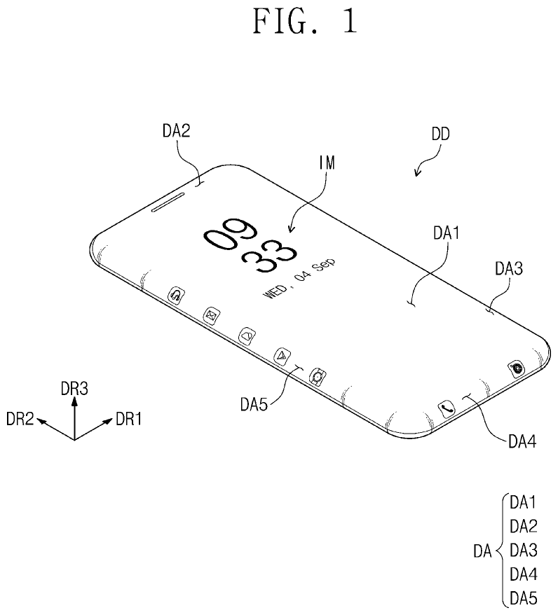

FIG. 1 is a perspective view illustrating a display device according to an embodiment of the inventive concepts.

Referring to FIG. 1, a display device DD may be activated by an electrical signal applied thereto. The display device DD may be realized in various forms. For example, the display device DD may be used for large-sized electronic devices (e.g., television sets and monitors) or small- or medium-sized electronic devices (e.g., mobile phones, tablets, car navigation systems, game machines, and smart watches). In the present embodiment, the display device DD may be a smart phone, as illustrated in FIG. 1.

A display region DA may be defined in the display device DD. The display region DA may include a first display region DA1, a second display region DA2, a third display region DA3, a fourth display region DA4, and a fifth display region DA5.

The first display region DA1 may be parallel to a plane defined by a first direction DR1 and a second direction DR2. A normal direction of the first display region DA1 may correspond to a thickness direction DR3 (hereinafter, a third direction) of the display device DD. In the present specification, the third direction DR3 will be used to differentiate a front or top surface and a rear or bottom surface of each element or member. The front and rear surfaces may be two surfaces that are opposite to each other in the third direction DR3. The third is direction DR3 may not be parallel to the first and second directions DR1 and DR2. In an embodiment, the first, second, and third directions DR1, DR2, and DR3 may be orthogonal to each other.

In the present specification, directions indicated by the first to third directions DR1, DR2, and DR3 may be relative concept, and in an embodiment, they may be used to indicate other directions. Furthermore, a surface defined by the first and second directions DR1 and DR2 may be defined as “a plane”, and an expression “when viewed in a plan view” may be used to mean that an object is seen in the third direction DR3.

The second display region DA2 may be a region that is extended from a first edge of the first display region DA1. The third display region DA3 may be a region that is extended from a second edge of the first display region DA1. The fourth display region DA4 may be a region that is extended from a third edge of the first display region DA1. The fifth display region DA5 may be a region that is extended from a fourth edge of the first display region DA1.

Each of the second, third, fourth, and fifth display regions DA2, DA3, DA4, and DA5 may be curved with a specific curvature.

Due to the curved shapes of the second, third, fourth, and fifth display regions DA2, DA3, DA4, and DA5 of the display device DD, an area of the display region DA to be seen by a user may be increased.

The display region DA may be used to display an image IM. FIG. 1 illustrates an example, in which a clock window and some icons are provided as a part of the image IM. In an embodiment, the clock window may be displayed on the first display region DA1, and the icons may be displayed on at least one of the second to fifth display regions D2, D3, D4, and D5.

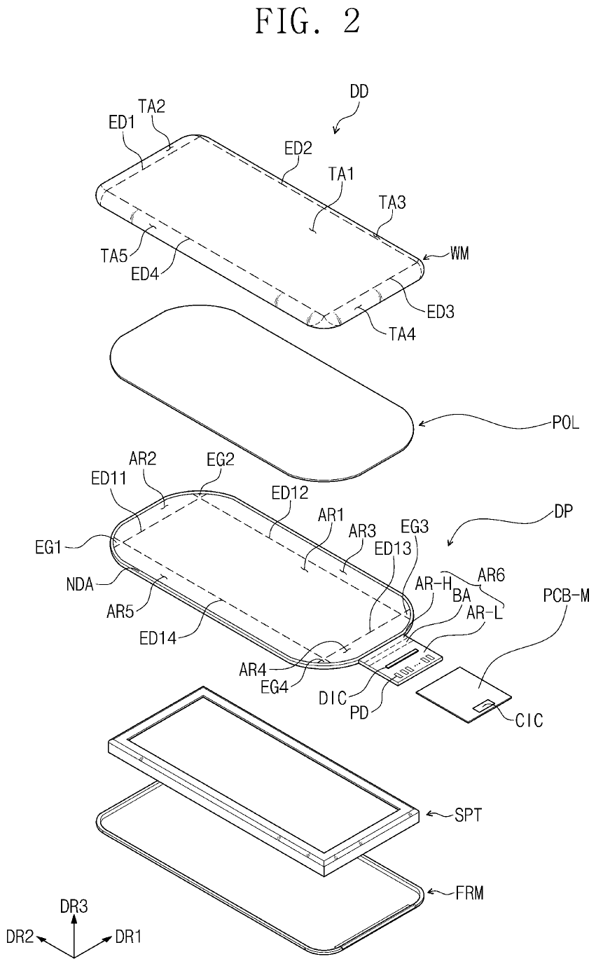

FIG. 2 is a perspective view illustrating an exploded structure of a display device is according to an embodiment of the inventive concepts.

Referring to FIG. 2, the display device DD may include a window WM, an optical film POL, a display panel DP, a printed circuit board PCB-M, a supporting member SPT, and a frame FRM.

The window WM may be disposed on the display panel DP. The window WM may protect the display panel DP from an external impact or the like. The window WM may be formed of or include a transparent material. For example, the window WM may be formed of or include at least one of glass or transparent synthetic resins.

The window WM may include transmission regions TA1, TA2, TA3, TA4, and TA5. The transmission regions TA1, TA2, TA3, TA4, and TA5 may include a first transmission region TA1, a second transmission region TA2, a third transmission region TA3, a fourth transmission region TA4, and a fifth transmission region TA5.

The first transmission region TA1 may be parallel to the first and second directions DR1 and DR2. The first transmission region TA1 may include a first edge ED1 extended in a direction parallel to the first direction DR1, a second edge ED2 extended from the first edge ED1 in a direction parallel to the second direction DR2, a third edge ED3 extended from the second edge ED2 in a direction parallel to the first direction DR1, and a fourth edge ED4 extended from the third edge ED3 in a direction parallel to the second direction DR2. The first edge ED1 and the third edge ED3 may be parallel to each other, and the second edge ED2 and the fourth edge ED4 may be parallel to each other.

The second transmission region TA2 may be extended from the first edge ED1 of the first transmission region TA1. The third transmission region TA3 may be extended from the second edge ED2 of the first transmission region TA1. The fourth transmission region TA4 is may be extended from the third edge ED3 of the first transmission region TA1. The fifth transmission region TA5 may be extended from the fourth edge ED4 of the first transmission region TA1.

At least a portion of each of the second, third, fourth, and fifth transmission regions TA2, TA3, TA4, and TA5 may be bent with a specific curvature.

The optical film POL may be disposed between the window WM and the display panel DP. The optical film POL may include, for example, a polarization film. The polarization film may reduce reflectance of an external light incident through the window WM.

The display panel DP may be an element producing the image IM (e.g., see FIG. 1). According to an embodiment of the inventive concepts, the display panel DP may be a light-emitting type display panel, but the inventive concepts are not limited to a specific type of the display panel DP. For example, the display panel DP may be an organic light emitting display panel or a quantum dot light emitting display panel. A light emitting layer of the organic light emitting display panel may be formed of or include an organic luminescent material. A light emitting layer of the quantum dot light emitting display panel may include quantum dots and/or quantum rods.

The display panel DP may include a first region AR1, a second region AR2, a third region AR3, a fourth region AR4, a fifth region AR5, and a sixth region AR6.

The first region AR1 may be parallel to the first and second directions DR1 and DR2. The first region AR1 may include a first edge ED11 extending in a direction parallel to the first direction DR1, a second edge ED12 extending in a direction parallel to the second direction DR2, a third edge ED13 extending in a direction parallel to the first direction DR1, and a fourth edge ED14 extending in a direction parallel to the second direction DR2. The first is edge ED11 and the third edge ED13 may be parallel to each other, and the second edge ED12 and the fourth edge ED14 may be parallel to each other.

The second region AR2 may be extended from the first edge ED11 of the first region AR1. The third region AR3 may be extended from the second edge ED12 of the first region AR1. The fourth region AR4 may be extended from the third edge ED13 of the first region AR1. The fifth region AR5 may be extended from the fourth edge ED14 of the first region AR1.

When viewed in a plan view, the first region AR1 may be overlapped with the first transmission region TA1. The second region AR2 may be overlapped with the second transmission region TA2. The third region AR3 may be overlapped with the third transmission region TA3. The fourth region AR4 may be overlapped with the fourth transmission region TA4. The fifth region AR5 may be overlapped with the fifth transmission region TA5.

The first region AR1 may display the image IM (e.g., see FIG. 1) through the first transmission region TA1. The second region AR2 may display the image IM (e.g., see FIG. 1) through the second transmission region TA2. The third region AR3 may display the image IM (e.g., see FIG. 1) through the third transmission region TA3. The fourth region AR4 may display the image IM (e.g., see FIG. 1) through the fourth transmission region TA4. The fifth region AR5 may display the image IM (e.g., see FIG. 1) through the fifth transmission region TA5.

The second, third, fourth, and fifth regions AR2, AR3, AR4, and AR5 may be bent with specific curvatures, such that they have shapes corresponding to the second, third, fourth, and fifth transmission regions TA2, TA3, TA4, and TA5.

In the present specification, the first region AR1 may be referred to as the first is display region DA1 (e.g., see FIG. 1). The second region AR2 may be referred to as the second display region DA2 (e.g., see FIG. 1). The third region AR3 may be referred to as the third display region DA3 (e.g., see FIG. 1). The fourth region AR4 may be referred to as the fourth display region DA4 (e.g., see FIG. 1). The fifth region AR5 may be referred to as the fifth display region DA5 (e.g., see FIG. 1).

A first corner region EG1 may be a surface adjacent to the second region AR2 and the fifth region AR5. The first corner region EG1 may be disposed between the second region AR2 and the fifth region AR5. The first corner region EG1 may have an edge of a convex shape, when viewed in a plan view. A second corner region EG2 may be a surface adjacent to the second region AR2 and the third region AR3. The second corner region EG2 may be disposed between the second region AR2 and the third region AR3. The second corner region EG2 may have an edge of a convex shape, when viewed in a plan view. A third corner region EG3 may be a surface adjacent to the third region AR3 and the fourth region AR4. The third corner region EG3 may be disposed between the third region AR3 and the fourth region AR4. The third corner region EG3 may have an edge of a convex shape, when viewed in a plan view. A fourth corner region EG4 may be a surface adjacent to the fourth region AR4 and the fifth region AR5. The fourth corner region EG4 may be disposed between the fourth region AR4 and the fifth region AR5. The fourth corner region EG4 may have an edge of a convex shape, when viewed in a plan view.

The sixth region AR6 may be extended from the fourth region AR4 and in the second direction DR2. The sixth region AR6 may include an upper region AR-H, a bending region BA, and a lower region AR-L.

The upper region AR-H may be extended from the fourth region AR4, the is bending region BA may be extended from the upper region AR-H, and the lower region AR-L may be extended from the bending region BA.

Pads PD may be disposed on the lower region AR-L, and a data driving circuit DIC may be mounted on the lower region AR-L. The pads PD may be electrically connected to the light emitting layer of the display panel DP. The data driving circuit DIC may provide data signals to the display region DA (e.g., see FIG. 1). The display panel DP may be electrically connected to the printed circuit board PCB-M via the pads PD. A control circuit CIC may be mounted on the printed circuit board PCB-M. The control circuit CIC may control the data driving circuit DIC.

The supporting member SPT may be disposed below the display panel DP. The supporting member SPT may support at least one of elements constituting the display panel DP.

The frame FRM may be disposed below the supporting member SPT. The frame FRM may be configured to contain at least a portion of the supporting member SPT, the display panel DP, and the window WM. In an embodiment, the frame FRM may be combined with the window WM.

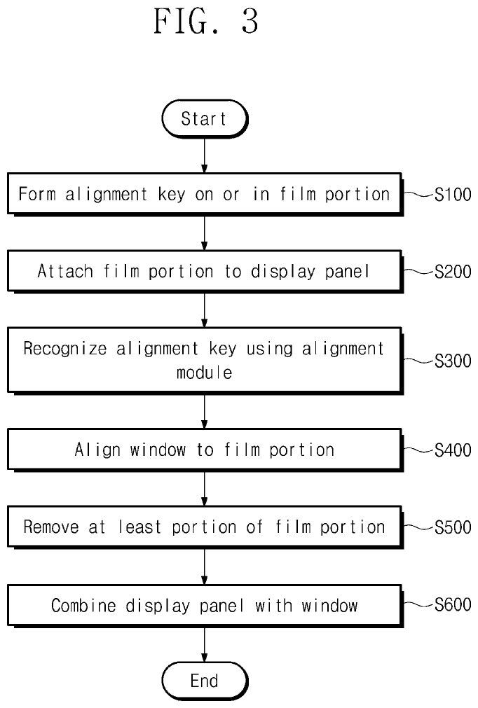

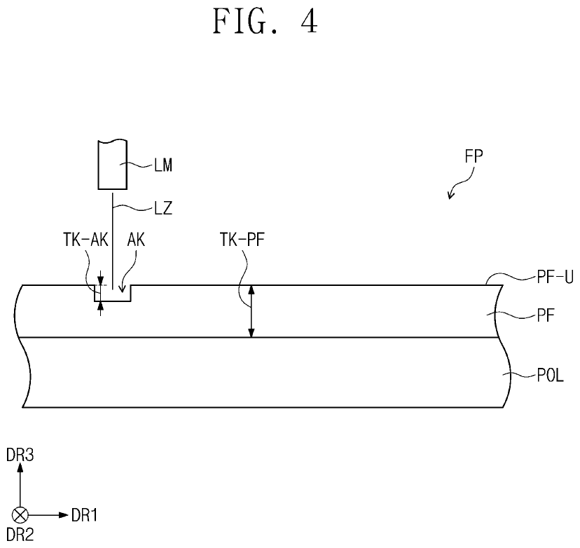

FIG. 3 is a flow chart illustrating a method of fabricating a display device according to an embodiment of the inventive concepts, and FIG. 4 is a sectional view illustrating a step of forming an alignment key, according to an embodiment of the inventive concepts.

Referring to FIGS. 3 and 4, a film portion FP may include the optical film POL and a protection film PF. The protection film PF may be disposed on the optical film POL. The protection film PF may protect the optical film POL.

An alignment key AK may be formed in the film portion FP (in S100). The alignment key AK may be formed in advance before attaching the film portion FP to the display is panel DP.

A laser irradiation unit LM may be placed over the protection film PF. The laser irradiation unit LM may be configured to irradiate a laser beam LZ. The laser beam LZ may include an excimer laser, an yttrium aluminum garnet (YAG) laser, a glass laser, an yttrium orthovanadate (YVO4) laser, or an Argon (Ar) laser.

The laser beam LZ may be used to perform a patterning process on a top surface PF-U of the protection film PF. For example, the laser beam LZ may be used to etch the top surface PF-U of the protection film PF in the third direction DR3 and thereby to form a hollow region. A thickness TK-PF of the protection film PF may be larger than or equal to a depth TK-AK of the hollow region of the alignment key AK. The hollow region may constitute the alignment key AK.

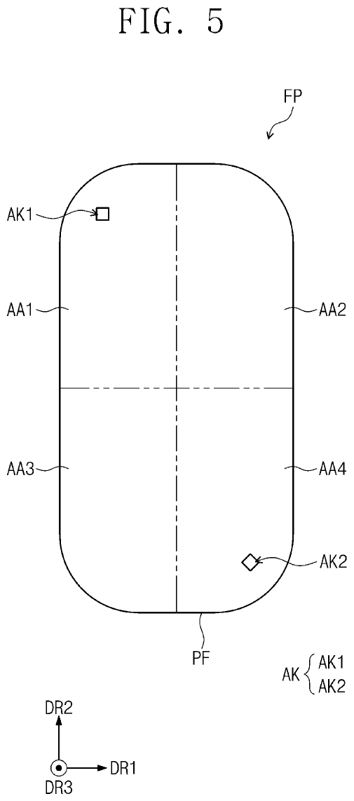

FIG. 5 is a plan view illustrating a film portion according to an embodiment of the inventive concepts.

Referring to FIGS. 3 and 5, the film portion FP may include a first alignment region AA1, a second alignment region AA2, a third alignment region AA3, and a fourth alignment region AA4.

The second alignment region AA2 may be adjacent to the first alignment region AA1 in the first direction DR1. The third alignment region AA3 may be adjacent to the first alignment region AA1 in the second direction DR2 and may be spaced apart from the second alignment region AA2. The fourth alignment region AA4 may be adjacent to the second alignment region AA2 in the second direction DR2 and may be adjacent to the third alignment region AA3 in the first direction DR1.

In an embodiment, a plurality of the alignment keys AK may be provided. The is alignment keys AK may include a first alignment key AK1 and a second alignment key AK2. FIG. 5 illustrates an example, in which two alignment keys AK are provided, but the number of the alignment keys is not limited thereto. For example, four alignment keys may be disposed in the first, second, third, and fourth alignment regions AA1, AA2, AA3, and AA4, respectively.

In an embodiment, the alignment keys AK may be formed in at least two regions of the first, second, third, and fourth alignment regions AA1, AA2, AA3, and AA4. For example, the first alignment key AK1 may be disposed in the first alignment region AA1, and the second alignment key AK2 may be disposed in the fourth alignment region AA4. However, the inventive concepts are not limited to this example, and the positions of the first and second alignment keys AK1 and AK2 may be changed.

In an embodiment, all or some of the alignment keys AK may be disposed in one of the first, second, third, and fourth alignment regions AA1, AA2, AA3, and AA4 of the protection film PF.

An example, in which one first alignment key AK1 is disposed in the first alignment region AA1, is illustrated, but the inventive concepts are not limited to this example. For example, two or more alignment keys may be disposed in the first alignment region AA1.

In an embodiment, the alignment keys AK may be formed to have at least two different shapes. For example, the first alignment key AK1 may be formed to have a rectangular shape, whereas the second alignment key AK2 may be formed to have a diamond shape. However, the inventive concepts are not limited to the shape of the alignment keys. For example, each of the alignment keys may be formed to have a polygonal, cross, elliptical, or circular shape. In an embodiment, all of the alignment keys AK may be formed to have the same shape.

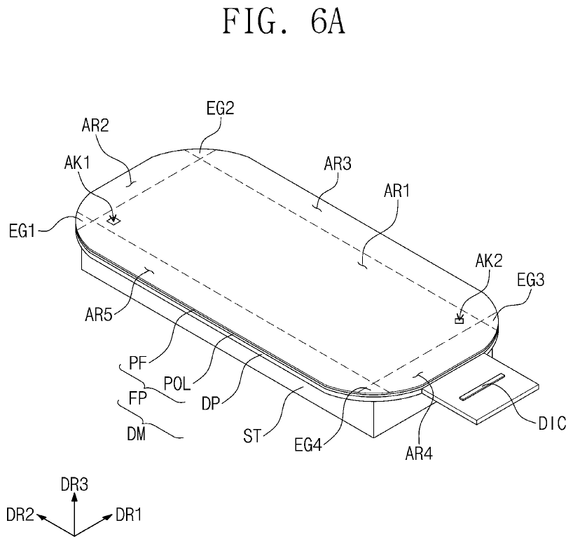

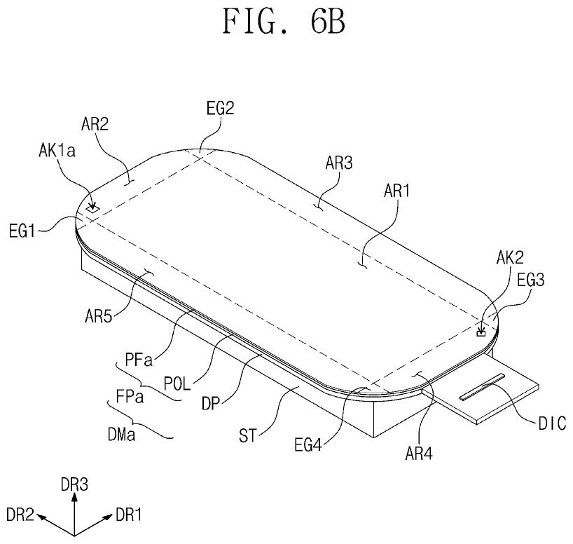

FIG. 6A is a perspective view illustrating a step of attaching a film portion on a display panel, according to an embodiment of the inventive concepts.

Referring to FIGS. 3 and 6A, a display module DM may be prepared. The display module DM may include the display panel DP and the film portion FP. The display panel DP may be disposed on a stage ST. The film portion FP with the alignment keys AK may be attached to the display panel DP (in S200).

A first adhesive layer (not shown) may be disposed between the display panel DP and the film portion FP. The first adhesive layer may be an optically clear adhesive (OCA) film, an optically clear resin (OCR) film, or a pressure sensitive adhesive (PSA) film.

In an embodiment, the film portion FP may be attached to the display panel DP such that the alignment keys AK1 and AK2 are disposed on the display region DA (e.g., see FIG. 1).

When viewed in a plan view, the alignment keys AK1 and AK2 may be disposed or formed at positions that are overlapped with the display region DA (e.g., see FIG. 1). The alignment keys AK1 and AK2 may be disposed or formed on the first region AR1. When viewed in a plan view, the alignment keys AK1 and AK2 may not be overlapped with the non-display region NDA (e.g., see FIG. 1).

In an embodiment, the alignment keys AK1 and AK2 may be disposed on the display region DA (e.g., see FIG. 1). In this case, the alignment keys AK1 and AK2 may be seen in front of the display panel DP, even when at least a portion of the display panel DP is bent. Accordingly, it may be possible to combine the window WM (e.g., see FIG. 2) to the display panel DP with improved accuracy. This may make it possible to realize a highly-reliable display device (e.g., DD in FIG. 1) and a method of fabricating the same.

FIG. 6B is a perspective view illustrating a step of attaching a film portion on a display panel, according to an embodiment of the inventive concepts.

Referring to FIGS. 3 and 6B, a display module DMa may include the display panel DP and a film portion FPa. The film portion FPa may be attached on the display panel DP (in S200). Alignment keys AK1a and AK2a may be formed at positions that are overlapped with the display region DA (e.g., see FIG. 1).

The alignment keys AK1a and AK2a may be formed or disposed on at least one of the second, third, fourth, and fifth regions AR2, AR3, AR4, and AR5. For example, the first alignment key AK1a may be formed or disposed on the second region AR2, and the second alignment key AK2a may be formed or disposed on the fourth region AR4. However, the inventive concepts are not limited to this example, and the positions of the first and second alignment keys AK1a and AK2a may be changed. When viewed in a plan view, the alignment keys AK1a and AK2a may not be overlapped with the non-display region NDA (e.g., see FIG. 2).

In certain embodiments, the alignment keys may be formed on not only the first region AR1 but also at least one of the second, third, fourth, and fifth regions AR2, AR3, AR4, and AR5.

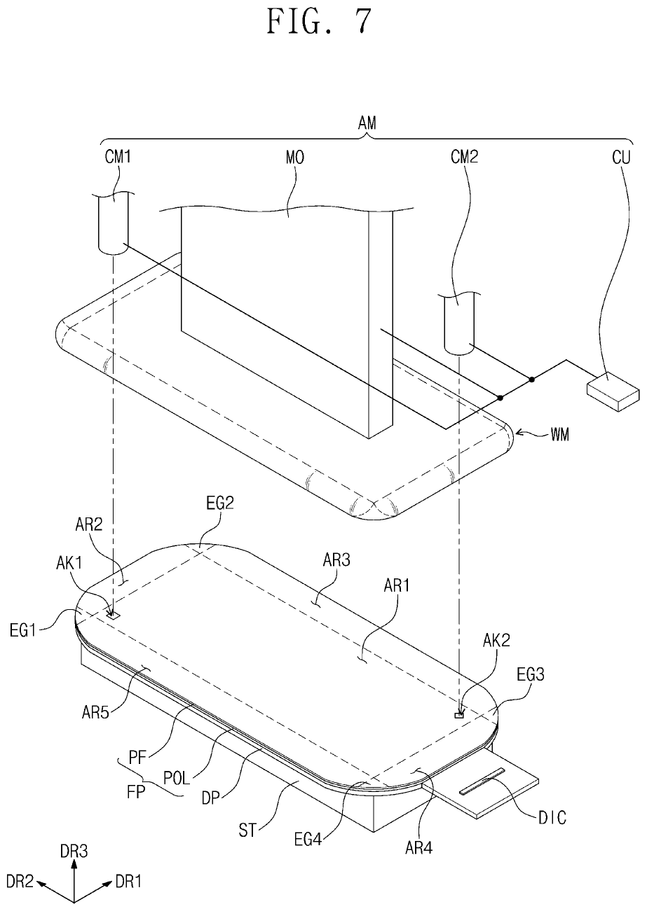

FIG. 7 is a perspective view illustrating a part of a method of fabricating a display device, according to an embodiment of the inventive concepts.

Referring to FIGS. 3 and 7, an alignment module AM may include a transfer module MO, cameras CM1 and CM2, and a control unit CU.

The transfer module MO may be configured to grip the window WM. For example, the transfer module MO may grip the window WM in a suction manner.

The cameras CM1 and CM2 may be used to recognize the alignment keys AK1 and AK2, respectively (in S300). The cameras CM1 and CM2 may be disposed to correspond to the alignment keys AK1 and AK2 in a one-to-one manner. The cameras CM1 and CM2 may include a first camera CM1 and a second camera CM2. When viewed in a plan view, the first camera CM1 may be overlapped with the first alignment key AK1. The second camera CM2 may be overlapped with the second alignment key AK2. FIG. 7 illustrates an example, in which two the cameras CM1 and CM2 are provided, but the inventive concepts are not limited to this example. In an embodiment, the number of the cameras may be equal to the number of the alignment keys. In certain embodiments, the number of the cameras may be larger or smaller than the number of the alignment keys.

In an embodiment, the alignment keys AK1 and AK2 may be disposed on the display region DA (e.g., see FIG. 1). A portion of the film portion FP with the alignment keys AK1 and AK2 may be removed, before the film portion FP is combined with the window WM. Thus, there may be no restriction on the sizes of the alignment keys AK1 and AK2. This may make it possible to increase the sizes of the alignment keys AK1 and AK2, and in this case, the alignment keys AK1 and AK2 may be more accurately recognized by the cameras CM1 and CM2. That is, the combining accuracy between the window WM and the display panel DP may be improved. This may make it possible to realize a highly-reliable display device (e.g., DD in FIG. 1) and a method of fabricating the same.

The window WM may be aligned to a desired position on the film portion FP by the alignment module AM (in S400). For example, the alignment position of the window WM may be adjusted by the transfer module MO. The recognizing of the alignment keys AK1 and AK2 (in S300) and the aligning of the window WM (in S400) may be simultaneously performed.

The control unit CU may store information on the position of the window WM aligned by the transfer module MO as position information. The position information may be obtained from the alignment keys AK1 and AK2 recognized by the cameras CM1 and CM2.

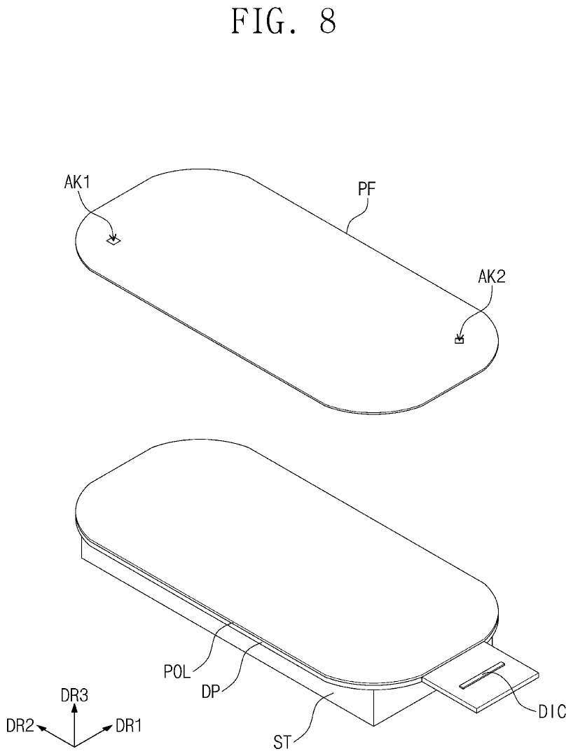

FIG. 8 is a perspective view illustrating a step of removing a portion of a film portion, according to an embodiment of the inventive concepts.

Referring to FIGS. 3 and 8, at least a portion of the film portion FP may be removed (in S500). For example, the protection film PF of the film portion FP may be removed from the display panel DP and the optical film POL.

Although the alignment keys AK1 and AK2 are formed or disposed to be overlapped with the display region DA (e.g., see FIG. 1), the presence of the alignment keys AK1 and AK2 may not affect the display region DA (e.g., see FIG. 1), because the protection film PF is removed.

In an embodiment, the film portion FP may include only the protection film PF, and in this case, the entirety of the film portion FP may be removed from the display panel DP.

In an embodiment, the protection film PF with the alignment keys AK1 and AK2 may be removed, before the combining of the window WM and the display panel DP. In this case, the alignment keys AK1 and AK2 may be formed at positions, which can be easily recognized by the alignment module AM (e.g., see FIG. 7), without any restriction on their positions. Accordingly, it may be possible to easily align the window WM and to improve accuracy in the alignment of the window WM. Furthermore, this may make it possible to improve the combining accuracy between the window WM and the display panel DP. Accordingly, it may be possible to realize a highly-reliable display device (e.g., DD in FIG. 1) and a method of fabricating the same.

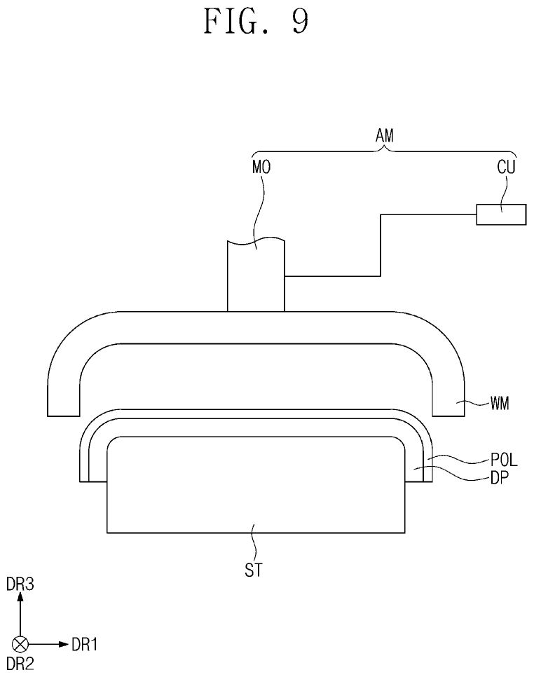

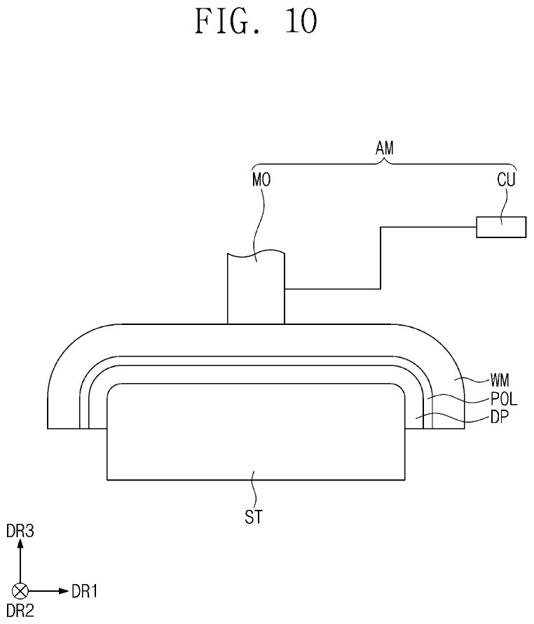

FIGS. 9 and 10 are sectional views illustrating a step of combining a window with a display panel, according to an embodiment of the inventive concepts.

Referring to FIGS. 3, 9, and 10, the display panel DP may be combined with the window WM (in S600). The transfer module MO may place the window WM on the display panel DP. The alignment module AM may align the window WM to a position on the display panel DP, using the position information on the aligned position of the window WM, stored in the control unit CU.

The display panel DP may be bent. The second region AR2 (e.g., see FIG. 2) may be bent to have a shape corresponding to that of the second transmission region TA2 (e.g., see FIG. 2). The third region AR3 (e.g., see FIG. 2) may be bent to have a shape corresponding to that of the third transmission region TA3 (e.g., see FIG. 2). The fourth region AR4 (e.g., see FIG. 2) may be bent to have a shape corresponding to that of the fourth transmission region TA4 (e.g., see FIG. 2). The fifth region AR5 (e.g., see FIG. 2) may be bent to have a shape corresponding to that of the fifth transmission region TA5 (e.g., see FIG. 2).

The window WM may be attached to the display panel DP. A second adhesive layer (not shown) may be disposed between the window WM and the optical film POL. The second adhesive layer may be an optically clear adhesive (OCA) film, an optically clear resin (OCR) film, or a pressure sensitive adhesive (PSA) film.

In an embodiment, the position information on the position of the window WM, which was determined in the step S300 of recognizing the alignment keys AK1 and AK2 (e.g., see FIG. 7) using the alignment module AM, may be stored in the control unit CU. The positions of the window WM and the transfer module AM may be changed, during the removing of the protection film PF (in S500). Here, a space to remove the protection film PF may be is provided. After the removing of the protection film PF, the display panel DP and the window WM may be re-aligned to each other using the stored position information. The combining of the display panel DP and the window WM (in S600) may be performed when they are aligned to each other. Accordingly, it may be possible to improve accuracy in the combining of the display panel DP and the window WM. This may make it possible to realize a highly-reliable display device (e.g., DD in FIG. 1) and a method of fabricating the same.

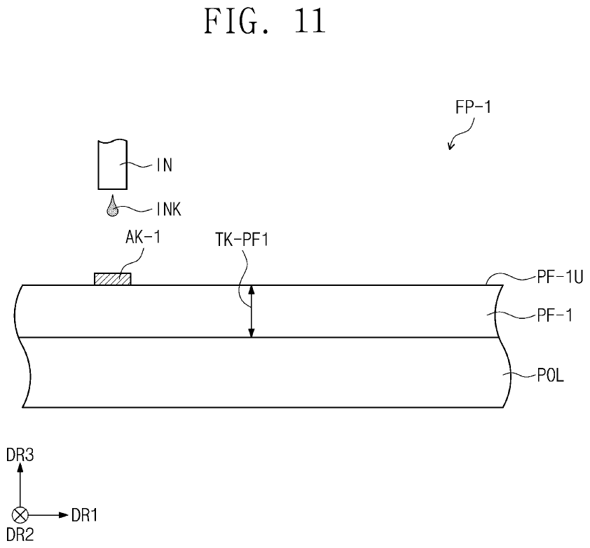

FIG. 11 is a sectional view illustrating a step of forming an alignment key on a film portion, according to an embodiment of the inventive concepts. In the following description of FIG. 11, an element previously described with reference to FIG. 4 may be identified by the same reference number without repeating an overlapping description thereof.

Referring to FIGS. 3, 4, and 11, an alignment key AK-1 may be formed on a film portion FP-1 (in S100). The forming of the alignment key AK-1 (in S100) may be performed before the step S200 of attaching the film portion FP-1 to the display panel DP.

The film portion FP-1 may include the optical film POL and a protection film PF-1. An ink ejection unit IN may be placed over the protection film PF-1. The ink ejection unit IN may eject an ink INK. The ink INK may be printed on a top surface PF-1U of the protection film PF-1. The alignment key AK-1 may be formed on the top surface PF-1U of the protection film PF-1.

In the case where the printing method using the ink ejection unit IN is used, it may be unnecessary to consider a thickness TK-PF1 of the protection film PF-1 in the forming of the alignment key AK-1, unlike the case of forming the alignment key AK with the laser irradiation unit LM. Thus, the process of forming the alignment key AK-1 on the film portion FP may be more easily performed.

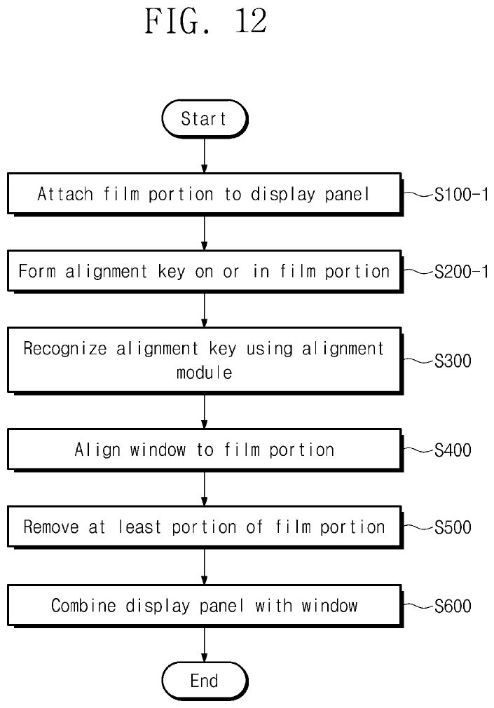

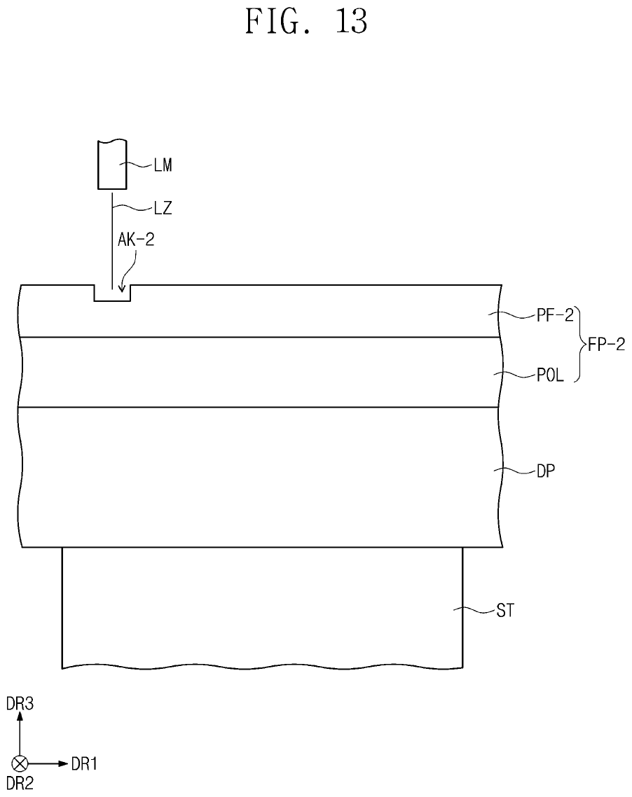

FIG. 12 is a flow chart illustrating a method of fabricating a display device, according to an embodiment of the inventive concepts, and FIG. 13 is a sectional view illustrating a step of forming an alignment key, according to an embodiment of the inventive concepts. In the following description of FIGS. 12 and 13, an element previously described with reference to FIGS. 3 and 4 may be identified by the same reference number without repeating an overlapping description thereof.

Referring to FIGS. 12 and 13, a film portion FP-2 may be attached to the display panel DP (in S100-1). Next, an alignment key AK-2 may be formed in the film portion FP-2 (S200-1). In other words, the step of forming the alignment key AK-2 may be performed on the film portion FP-2 attached to the display panel DP.

In an embodiment, the step of forming the alignment key AK-2 (in S200-1) may be performed concurrently with a step of a display device fabrication process, in which the laser beam LZ is used. For example, the step of forming the alignment key AK-2 in the film portion FP-2 using the laser beam LZ and a step of cutting the display panel DP using the laser beam LZ may be performed in the same process. In this case, it may be possible to reduce a total process time taken to fabricate a display device.

In an embodiment, the alignment key AK-2 may be disposed to be overlapped with the display region DA (e.g., see FIG. 1). A protection film PF-2, in which the alignment key AK-2 is formed, may be removed before the window WM and the display panel DP are combined with each other, and in this case, the alignment key AK-2 may be formed at a position, which can be easily recognized by the alignment module AM, without any restriction on its position. That is, the combining accuracy between the window WM and the display panel DP may be improved. This may make it possible to realize a highly-reliable display device (e.g., is DD in FIG. 1) and a method of fabricating the same.

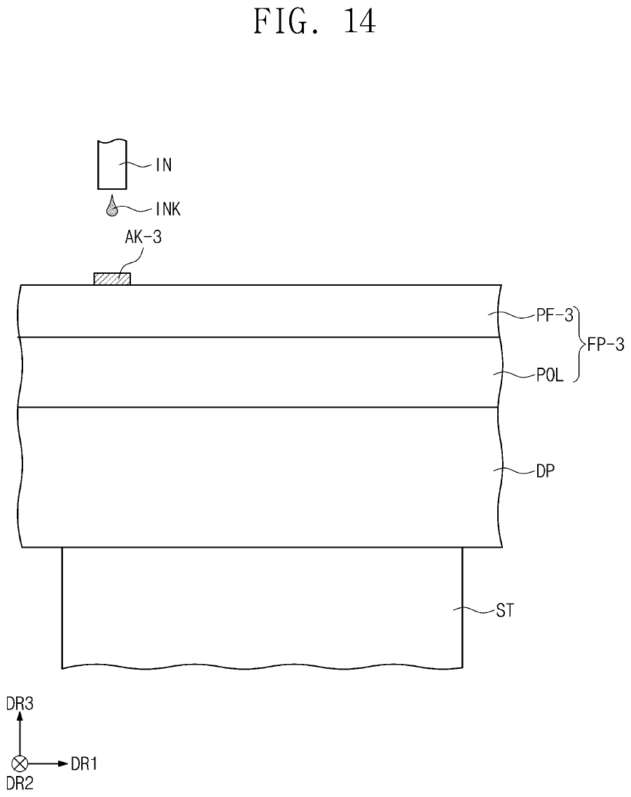

FIG. 14 is a sectional view illustrating a step of forming an alignment key, according to an embodiment of the inventive concepts. In the following description of FIG. 14, an element previously described with reference to FIG. 11 may be identified by the same reference number without repeating an overlapping description thereof.

Referring to FIGS. 12 and 14, a film portion FP-3 may be attached to the display panel DP. Next, an alignment key AK-3 may be formed on the film portion FP-3. In other words, the step of forming the alignment key AK-3 may be performed on the film portion FP-3 attached to the display panel DP.

The ink ejection unit IN may be placed over a protection film PF-3. The alignment key AK-3 may be formed by using the ink INK ejected from the ink ejection unit IN.

According to an embodiment of the inventive concepts, an alignment key, which is used to align a window to a display panel, may be formed on a film portion to be removed. This may make it possible to dispose the alignment key at a position overlapped with a display region of the display panel. Furthermore, the alignment key may be placed in front of the display panel, even when at least a portion of the display panel is bent. Accordingly, the window may be aligned to the display panel with high alignment accuracy, and thus, the process of combining the window with the display panel may be performed with improved accuracy.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A method of fabricating a display device, comprising:
preparing a display panel;
attaching a film portion to the display panel;
forming an alignment key on or in the film portion;
recognizing the alignment key using an alignment module having a camera;
aligning a window to the film portion using the alignment module;
removing at least a portion of the film portion; and
combining the display panel with the window.

2. The method of claim 1, wherein the film portion comprises an optical film and a protection film disposed on the optical film, and
the forming of the alignment key on or in the film portion comprises forming the alignment key on or in a top surface of the protection film.

3. The method of claim 2, wherein the removing of at least the portion of the film portion comprises removing the protection film.

4. The method of claim 1, wherein the forming of the alignment key comprises patterning a top surface of the film portion using a laser beam.

5. The method of claim 1, wherein the forming of the alignment key comprises printing an ink on a top surface of the film portion.

6. The method of claim 1, wherein the forming of the alignment key is performed before the attaching of the film portion to the display panel.

7. The method of claim 1, wherein the forming of the alignment key is performed after the attaching of the film portion to the display panel.

8. The method of claim 1, wherein the display panel comprises:
a first region including a first edge, a second edge extending in a direction crossing the first edge, a third edge parallel to the first edge, and a fourth edge parallel to the second edge;
a second region, which is extended from the first edge, and at least a portion of which is bent;
a third region, which is extended from the second edge, and at least a portion of which is bent;
a fourth region, which is extended from the third edge, and at least a portion of which is bent; and
a fifth region, which is extended from the fourth edge, and at least a portion which is bent.

9. The method of claim 8, wherein the alignment key is formed on at least one of the second to fifth regions.

10. The method of claim 8, wherein the alignment key is formed on the first region.

11. The method of claim 1, wherein the forming of the alignment key comprises forming a plurality of alignment keys in at least two different shapes.

12. The method of claim 1, wherein the display panel comprises a display region and a non-display region adjacent to the display region, and
the alignment key is formed at a position overlapped with the display region.

13. The method of claim 1, wherein the alignment module further comprises a control unit, and
the method further comprises storing position information on an aligned position of the window, in the control unit.

14. The method of claim 13, further comprising aligning the window, using the position information stored in the control unit, after the removing of at least the portion of the film portion.

15. The method of claim 1, wherein the recognizing of the alignment key and the aligning of the window are performed simultaneously.

16. The method of claim 1, wherein the alignment key provides in plural,
the film portion comprises:
a first alignment region;
a second alignment region adjacent to the first alignment region;
a third alignment region adjacent to the first alignment region and spaced apart from the second alignment region; and
a fourth alignment region adjacent to the second and third alignment regions, and
the forming of the alignment key comprises forming the plurality of alignment keys on or in at least two regions of the first to fourth alignment regions.

17. A display module, comprising:
a display panel including a display region and a non-display region adjacent to the display region;
an optical film disposed on the display panel; and
a protection film disposed on the optical film,
wherein at least one alignment key is provided on or in a top surface of the protection film.

18. The display module of claim 17, wherein the alignment key is overlapped with the display region, when viewed in a plan view.

19. The display module of claim 17, wherein the alignment key is defined by a hollow region, which is recessed downward from the top surface of the protection film, and
a depth of the hollow region is smaller than a thickness of the protection film.

20. The display module of claim 17, wherein the alignment key comprises an ink pattern provided on the top surface of the protection film.
